(19) United States
(12) Patent Application Publication
(10) Pub. No.: US 2024/0332133 A1
(43) Pub. Date: Oct. 3, 2024

(54) CARRIER WITH EMBEDDED ELECTRICAL CONNECTION, COMPONENT AND METHOD FOR PRODUCING A CARRIER

(71) Applicant: ams-OSRAM International GmbH, Regensburg (DE)

(72) Inventor: Michael Zitzlsperger, Regensburg (DE)

(21) Appl. No.: 18/576,334

(22) PCT Filed: Jul. 26, 2022
(86) PCT No.: PCT/EP2022/070963

§ 371 Date: Jan. 3, 2024

(30) Foreign Application Priority Data
Jul. 29, 2021 (DE) 10 2021 119 707.4

(51) Int. Cl. H01L 23/495; H01L 23/00; H01L 25/065

(52) U.S. Cl. CPC H01L 23/49506; H01L 23/49548; H01L 23/49575; H01L 24/37; H01L 24/45; H01L 25/0652; H01L 2224/37005; H01L 2224/3702; H01L 2224/45005; H01L 2224/4502; H01L 2924/01029; H01L 2924/096; H01L 2924/181

(57) ABSTRACT

In an embodiment a carrier includes a shaped body, a lead frame, a first electrode and a second electrode, wherein the first electrode includes a first subregion of the lead frame, a second subregion of the lead frame, and an electrical connection connecting the first subregion to the second subregion, wherein the first subregion is laterally spaced from the second subregion by an intermediate region, wherein the lead frame has at least one subsection, which is located at least in places in the intermediate region and thus in a lateral direction between the first subregion and the second subregion of the first electrode, wherein the intermediate region is at least partially filled by the shaped body or directly adjoins the shaped body, the electrical connection being embedded in the shaped body, and wherein the subsection of the lead frame is neither a subregion of the first electrode nor a subregion of the second electrode.

### CROSS-REFERENCE TO RELATED APPLICATIONS

This patent application is a national phase filing under section 371 of PCT/EP2022/070963, filed Jul. 26, 2022, which claims the priority of German patent application 102021119707.4, filed Jul. 29, 2021, each of which is incorporated herein by reference in its entirety.

### TECHNICAL FIELD

A carrier having a lead frame, a component having a carrier, and a method for producing a carrier are disclosed.

### BACKGROUND

Lead-frame-based substrates for LEDs, for example, are delimiting in the fineness of their structures and often do not offer ideal possibilities with regard to rewiring. In fact, rewiring in a so-called QFN component (Quad Flat No-Lead component) is so limited in practice that it is often not considered. Instead, bonding wires are often used. However, prior to an injection molding process, wire bonding is only possible on solid surfaces because there is a solder pad under each bonding wire, which after the injection molding process should be in a cavity and sufficiently far away from walls of the cavity. The compactness of a component with such a structure is therefore negatively affected.

### SUMMARY

Embodiments provide a compact and simplified manufacturable carrier, in particular a compact and simplified manufacturable component with such a carrier. Further embodiments comprise a cost-effective and simplified method for producing a compact carrier.

Here, a possibility is proposed to supplement a carrier, for example in the form of a lead frame-based substrate, such as in the form of a so-called Rt-QFN substrate (route-able Quad Flat No-Lead substrate), with at least one embedded electrical connection or with multiple embedded electrical connections. For example, one electrical connection or a plurality of electrical connections may be embedded in the carrier. The electrical connection may be a wiring, for example in the form of a metal wire or a metal ribbon, such as in the form of a copper wire or a copper ribbon. The electrical connection may also be a planar electrical connection. For example, a dielectric may first be applied and an electrical contact deposited thereon. If necessary, another film can be applied to the electrical connection. Forming the electrical connection is not limited to wire bonding as a technology. Other alternative methods can be used to apply the electrical connection, especially a planar electrical connection.

This enables more complex rewiring with significant space savings, saves costs, and leads to improvements in conventional products and processes. For example, in a casting process, molding process, or silicone processes, a bottom side adhesive tape on the carrier can be avoided. Mounting and contacting semiconductor chips on such a carrier or assembling such a carrier can be performed in a simplified manner.

According to at least one embodiment of the carrier, it comprises at least a lead frame, a shaped body and an electrical connection, wherein the electrical connection is embedded in the shaped body.

The lead frame can be enclosed by the shaped body at least in places in the lateral direction. For example, the lead frame has subregions or subsections that are spatially spaced from one another in lateral directions. The subregions and/or subsections of the lead frame can be laterally enclosed by the shaped body and thereby mechanically connected to one another. However, it is possible for the lead frame to have some subregions and/or subsections that are arranged on the shaped body but not laterally enclosed by the shaped body. For example, these subregions and/or subsections are directly adjacent to the shaped body.

In the case of a QFN carrier or QFN component, it is possible for outer side surfaces of the lead frame to be partially or completely covered by the material of the shaped body. However, it is also possible that the lead frame and the shaped body are flush with each other along the lateral direction in places. For example, the shaped body has a side surface on which the lead frame is accessible in places. It is further possible for the shaped body to have a plurality of such side surfaces on which the lead frame is exposed in places. The side surfaces of the lead frame may be formed in places by surfaces of the shaped body. However, in the case of a QFN substrate or in the case of a QFN carrier, the lead frame in particular does not protrude laterally from the shaped body. The shaped body can be of contiguous and/or one-piece design.

A lateral direction is understood to be a direction that is directed in particular parallel to a main extension surface of the lead frame or parallel to a mounting surface of the lead frame. A vertical direction is understood to be a direction which is directed in particular perpendicularly to the main extension surface of the lead frame or to the mounting surface of the lead frame. The vertical direction and the lateral direction are orthogonal to each other.

The shaped body can be formed from an electrically insulating material. For example, the shaped body is formed from a plastic material, in particular from a casting material and/or from an injection molding compound, from silicone, from synthetic resin or from similar materials.

The electrical connection can be in the form of a metal wire, for example, a copper wire. In addition to copper, other metals are also suitable. The electrical connection is formed in particular to electrically connect spatially spaced subsections and/or subregions of the lead frame to one another. Except at the contact points with the lead frame, the electrical connection may be completely embedded in the shaped body. The carrier may include a plurality of such embedded electrical connections. It is possible for the electrical connection to be formed as a planar electrical connection.

According to at least one embodiment of the carrier, it comprises a first electrode and a second electrode different from the first electrode. The lead frame has a first subregion and a second subregion laterally spaced from the first subregion. The first subregion and the second subregion may be assigned to the same electrode of the carrier. For example, via the shaped body, the first subregion and the second subregion are mechanically connected to each other. In particular, via the electrical connection, the first subregion and the second subregion are electrically conductively connected to each other.

The lead frame has a subsection which can be assigned to one of the electrodes of the carrier or be electrically neutral. In particular, the subsection is located in a lateral direction at least in places between the first subregion and the second subregion. In top view, the subsection may be bridged or under-bridged by the electrical connection. In top view, the subsection may overlap with the electrical connection. However, the shaped body electrically insulates the subsection from the electrical connection.

In at least one embodiment of a carrier, it comprises a shaped body and a lead frame. The carrier comprises a first electrode and a second electrode different from the first electrode, wherein the first electrode comprises a first subregion of the lead frame, a second subregion of the lead frame, and an electrical connection, and wherein the electrical connection electrically conductively connects the first subregion to the second subregion. The first subregion is laterally spaced from the second subregion by an intermediate region. The lead frame has at least one subsection that is at least in places located in the intermediate region, and thus in lateral directions between the first subregion and the second subregion of the first electrode. The intermediate region is at least partially filled by the shaped body or is directly adjacent to the shaped body. The electrical connection is embedded in the shaped body.

By embedding the electrical connection in the shaped body, the rewiring of the subregions of the lead frame can be carried out safely. Due to the embedding in the shaped body, the electrical connection is sufficiently protected from external environmental influences or external mechanical influences. In addition, possible electrical short circuits between the electrical connection and further subsections of the lead frame or further electrical connections of the carrier can be greatly prevented. By embedding the electrical connection or connections in the shaped body, the carrier can be configured to be particularly compact and mechanically stable.

The lead frame can have a mounting surface in places for receiving a semiconductor chip, wherein the mounting surface is free from being covered by material of the shaped body. In particular, the shaped body is located on the bottom side of the lead frame or the carrier. The bottom side of the carrier may be formed in places by surfaces of the shaped body. The carrier has a top side which is in places formed by the mounting surface. In top view of the top side of the carrier, the lead frame may be free from being covered by material of the shaped body. The shaped body is thus different from an encapsulation layer which is arranged on the top side of the carrier, for example, and covers the semiconductor chip or possible bonding wire connections or planar electrical connections.

According to at least one embodiment of the carrier, the subsection is electrically insulated from the electrical connection by the shaped body. In top view of the shaped body, the subsection may overlap with the electrical connection. The subsection may thus be laterally bridged by the electrical connection.

It is possible for the carrier to have a plurality of first subregions, a plurality of second subregions, and/or a plurality of subsections. The carrier may have a plurality of electrical connections each embedded in the shaped body, wherein the electrical connections embedded in the shaped body each electrically conductively connect two subregions to one another while bridging one of the subsections. The subregions and the subsections of the lead frame can be formed as conductor tracks or as connection pads, such as soldering pads or chip pads. In particular, it is possible that the first subregion, the second subregion, or the subsection includes a mounting surface for receiving a semiconductor chip or a connection surface for receiving a bonding wire connection or a planar electrical connection. Furthermore, it is possible that the subsection is implemented as an electrically neutral element of the lead frame.

According to at least one embodiment of the carrier, the subsection is free of lateral covering by material of the shaped body. The subsection has a surface facing the electrical connection, which can be directly adjacent to the shaped body. Except for the surface facing the electrical connection, the subsection may be free from being covered by material of the shaped body.

According to at least one embodiment of the carrier, it has a top side which is configured to receive at least one semiconductor chip. The top side can be formed in places by surfaces of the first subregion, the second subregion and/or the subsection. For example, the top side is free from being covered by material of the shaped body. The carrier has a bottom side facing away from the top side. The bottom side may be formed in places by surfaces of the lead frame and in places by surfaces of the shaped body.

According to at least one embodiment of the carrier, the first subregion and the second subregion are enclosed by the shaped body in lateral directions. The shaped body may mechanically connect the first subregion and the second subregion to each other. The shaped body may be directly adjacent to further subsections of the lead frame, as a result of which the subsections of the lead frame are also mechanically connected to the subregions of the lead frame. The shaped body may be contiguous and of one-piece construction. It is possible for all components of the lead frame, i.e. all subsections and all subregions of the lead frame, to be mechanically connected to one another by the shaped body.

According to at least one embodiment of the carrier, the first subregion, the second subregion, and/or the subsection of the lead frame are formed from the same material or same materials.

According to at least one embodiment of the carrier, the subsection of the lead frame is neither a subregion of the first electrode nor a subregion of the second electrode. In other words, the subsection may be electrically neutral in operation of a component having such a carrier. Alternatively, it is possible for the subsection, which is neither a subregion of the first electrode nor a subregion of the second electrode, to be at a different electrical potential than the first electrode and the second electrode during operation of the component. In this case, the “electrically neutral” subsection is not necessarily to be understood in the sense of a floating subregion.

According to at least one embodiment of the carrier, the subsection of the lead frame is formed as a sealing lip. The subsection of the lead frame formed as a sealing lip is arranged, for example, in the lateral direction between the first subregion and the second subregion of the first electrode. The subsection formed as a sealing lip may be configured to prevent the second subregion from being covered, for example, by a casting material. For example, a casting body is formed on the carrier or around the carrier. In top view, the casting body may cover the lead frame in places. Due to the presence of the subsection configured as a sealing lip, the casting material can be prevented from entering inner regions of the top side of the carrier.

According to at least one embodiment of the carrier, the first subregion, the second subregion, and the subsection of the lead frame are each integrally formed. For example, the subsection is a subregion of the second electrode.

According to at least one embodiment of the carrier, the first subregion and the second subregion are each formed from at least two sublayers arranged one above the other. The lead frame may have at least two subsections. For example, the shaped body with the electrical connection embedded therein is arranged along the vertical direction between the at least two subsections.

According to at least one embodiment of the carrier, a subsection of the at least two subsections is assigned to the second electrode. For example, another subsection of the at least two subsections is neither a subregion of the first electrode nor a subregion of the second electrode. The carrier may have a plurality of such sections.

According to at least one embodiment of the carrier, the first subregion comprises a first sublayer and a second sublayer disposed on the first sublayer. The second subregion may comprise a first sublayer and a second sublayer disposed on the first sublayer. In particular, the shaped body is arranged along the vertical direction between the first sublayer of the first subregion and the second sublayer of the first subregion. The first sublayer of the first subregion and the first sublayer of the second subregion may be formed from the same material. For example, the second sublayer of the first subregion and the second sublayer of the second subregion are formed from the same material.

According to at least one embodiment of the carrier, the first subregion, the second subregion or/and the subsection is/are formed as electrical conductor track/s on the shaped body. The carrier may have a plurality of such subsections and subregions. Due to the electrical connections embedded in the shaped body, a plurality of spatially spaced conductor tracks assigned to a first electrode can be electrically conductively connected to one another. The further spatially spaced conductor tracks assigned to a second electrode may be located on the same wiring plane as the electrical conductor tracks of the first electrode. At the crossing points of the conductor paths, some conductor paths may be bridged by the electrical connections embedded in the shaped body.

According to at least one embodiment of the carrier, the first subregion, the second subregion, or the subsection has a mounting surface configured to receive a semiconductor chip or a further electrical connection of the first electrode or a further electrical connection of the second electrode. The further electrical connection of the first electrode or the second electrode may be a bonding wire connection or a planar electrical connection. For example, the further electrical connection, for example in the form of a bonding wire connection or in the form of a planar electrical connection, is configured for electrically contacting a semiconductor chip arranged on the first subregion, on the second subregion or on the subsection.

In at least one embodiment of a component, it has a carrier, in particular a carrier described herein, and at least one semiconductor chip. The semiconductor chip is arranged on the carrier and may be electrically conductively connected to the lead frame. The semiconductor chip is spatially spaced from the shaped body, for example, and in particular is thus not covered by the shaped body. For example, the semiconductor chip is arranged on the first subregion, on the second subregion or on the subsection or on a further subregion or on a further subsection of the lead frame. Thus, the semiconductor chip is not in particular directly adjacent to the shaped body. The component may have a plurality of semiconductor chips arranged on different subregions or subsections of the lead frame.

According to at least one embodiment of the component, it has a casting body. The casting body can cover an edge region of the carrier or of the lead frame. For example, several subregions or several subsections of the lead frame may be covered by the casting body. In top view, the casting body may frame an inner region of the component. It is possible that at least a subsection of the lead frame is formed as a sealing lip, which, in top view, is located along the lateral directions between the casting body and the inner region of the component. The subsection formed as a sealing lip extends, for example, along one edge or along a plurality of edges of the inner region of the component. It is also possible that the subsection formed as a sealing lip is frame-like.

In at least one embodiment of a method for producing a carrier, in particular a carrier described herein, having a lead frame and a shaped body, a contiguous metal layer is provided. Separation trenches are formed in the metal layer such that the metal layer initially continues to remain contiguous. At least one electrical connection is provided in at least one of the separation trenches. The separation trenches are filled with material of the shaped body, as a result of which the electrical connection is embedded in the shaped body. Further separation trenches are formed through the metal layer to partially expose the shaped body, wherein the further separation trenches each overlap with one of the separation trenches. The contiguous metal layer is divided by the separation trenches and the further separation trenches into at least a first electrode and a second electrode different from the first electrode.

The first electrode comprises at least a first subregion and a second subregion of the lead frame and the electrical connection, wherein the electrical connection electrically connects the first subregion to the second subregion. The first subregion is laterally spaced from the second subregion by an intermediate region. The lead frame has at least a subsection located in the intermediate region and thus in lateral directions between the first subregion and the second subregion of the first electrode. The intermediate region is at least partially filled by the shaped body or is immediately adjacent to the shaped body.

According to at least one embodiment of the method, a further metal layer is formed on the metal layer and on the shaped body. The shaped body is arranged in the vertical direction between the metal layer and the further metal layer. The further metal layer is applied in a structured manner or is structured subsequently so that the further metal layer has additional separation trenches. The additional separation trenches can extend along the vertical direction through the further metal layer and divide the further metal layer into a plurality of spatially separated sublayers.

According to at least one embodiment of the method, a shaped body or a casting body is applied to and around the lead frame by a plastic molding process or by a casting process.

The term “casting process” or “plastic molding process” is generally understood to mean a method by which a casting/molding compound is shaped and, if necessary, cured according to a predetermined form, preferably under the action of pressure. In particular, the term “casting process” or “plastic molding process” includes at least dispensing, jet dispensing, molding, injection molding, transfer molding and compression molding. In particular, the shaped body or the casting body is formed from a plastic material, in particular from a molding material or from a castable material. In particular, the shaped body or the casting body is formed by a film-assisted molding process.

The method described here is particularly suitable for producing a carrier or component with such a carrier described here. The features described in connection with the carrier or with the component can therefore also be used for the method, and vice versa.

The following text describes other aspects of the present disclosure, with each aspect numbered to facilitate reference to features of other aspects.

Aspect 1: A carrier comprising a shaped body and a lead frame, wherein
the carrier comprises a first electrode and a second electrode different from the first electrode,
the first electrode comprises a first subregion of the lead frame, a second subregion of the lead frame, and an electrical connection, the electrical connection electrically connecting the first subregion to the second subregion,
the first subregion is laterally spaced from the second subregion by an intermediate region,
the lead frame has at least one subsection which is located at least in places in the intermediate region and thus in lateral directions between the first subregion and the second subregion of the first electrode, and
the intermediate region is at least partially filled by the shaped body or is directly adjacent to the shaped body, wherein the electrical connection is embedded in the shaped body.

Aspect 2: Carrier according to aspect 1,
wherein the subsection is electrically insulated from the electrical connection by the shaped body and, in top view of the shaped body, overlaps with the electrical connection.

Aspect 3: Carrier according to any of the preceding aspects,
wherein the subsection is free from lateral covering by material of the shaped body.

Aspect 4: Carrier according to any of the preceding aspects,
having a top side configured to receive at least one semiconductor chip, wherein
the top side is formed in places by surfaces of the first subregion, the second subregion and/or the subsection, and
the top side is free from being covered by material of the shaped body.

Aspect 5: Carrier according to any of the preceding aspects,
wherein the first subregion and the second subregion are enclosed by the shaped body in lateral directions, as a result of which the first subregion and the second subregion are mechanically connected to each other by the shaped body.

Aspect 6: A carrier according to any of the preceding aspects, wherein the first subregion, the second subregion, and the subsection of the lead frame are formed of the same material.

Aspect 7: Carrier according to any of Aspects 1 to 6,
wherein the subsection of the lead frame is neither a subregion of the first electrode nor a subregion of the second electrode.

Aspect 8: A carrier according to the preceding aspect,
wherein the subsection of the lead frame is formed as a sealing lip which is arranged in the lateral direction between the first subregion and the second subregion of the first electrode, the subsection formed as a sealing lip being configured to prevent the second subregion from being covered by a casting material.

Aspect 9: Carrier according to any of Aspects 1 to 6,
wherein the first subregion, the second subregion and the subsection of the lead frame are each formed in one-piece, and the subsection is a subregion of the second electrode.

Aspect 10: Carrier according to any of Aspects 1 to 8,
wherein the first subregion and the second subregion are each formed from at least two sublayers arranged one above the other, wherein
the lead frame has at least two subsections, and
the shaped body with the electrical connection embedded therein is arranged along vertical direction between the at least two subsections.

Aspect 11: The carrier according to the preceding aspect, wherein.
a subsection of the at least two subsections is assigned to the second electrode, and
a further subsection of the at least two subsections is neither a subregion of the first electrode nor a subregion of the second electrode.

Aspect 12: The carrier according to any one of aspects 1 to 8 or 10 to 11, wherein.
the first subregion comprises a first sublayer and a second sublayer disposed on the first sublayer, and
the second subregion comprises a first sublayer and a second sublayer disposed on the first sublayer,
wherein
the shaped body is arranged along vertical direction between the first sublayer of the first subregion and the second sublayer of the first subregion,
the first sublayer of the first subregion and the first sublayer of the second subregion are formed of the same material, and
the second sublayer of the first subregion and the second sublayer of the second subregion are formed from the same material.

Aspect 13: Carrier according to any one of the preceding aspects 1 to 6 or 9 to 12, wherein the first subregion, the second subregion, or/and the subsection is/are configured as an electrically conductive track/s on the shaped body.

Aspect 14: Carrier of any one of preceding aspects 1 to 6 or 9 to 12, wherein the first subregion, the second subregion, or the subsection comprises a mounting surface configured to receive a semiconductor chip or a further electrical connection of the first electrode or a further electrical connection of the second electrode.

Aspect 15: A component comprising the carrier according to any one of the preceding aspects and comprising at least one semiconductor chip, wherein
the semiconductor chip is arranged on the carrier and electrically conductively connected to the lead frame, and
the semiconductor chip is spatially spaced from the shaped body and thus not covered by the shaped body.

Aspect 16: A method for producing a carrier comprising a lead frame and a shaped body, comprising following method steps:
Providing a contiguous metal layer;
formation of separation trenches in the metal layer in such a way that the metal layer initially remains contiguous;
attaching at least one electrical connection in at least one of the separation trenches;
filling the separation trenches with material of the shaped body, as a result of which the electrical connection is embedded in the shaped body; and
forming further separation trenches through the metal layer to partially expose the shaped body, wherein the further separation trenches each overlap with one of the separation trenches, so that
the contiguous metal layer is divided by the separation trenches and the further separation trenches into at least a first electrode and a second electrode different from the first electrode,
the first electrode comprises at least a first subregion and a second subregion of the lead frame and the electrical connection, wherein the electrical connection electrically connects the first subregion to the second subregion,
the first subregion is laterally spaced from the second subregion by an intermediate region,
the lead frame has at least one subsection which is located in the intermediate region and thus in lateral directions between the first subregion and the second subregion of the first electrode, and
the intermediate region is at least partially filled by the shaped body or is directly adjacent to the shaped body.

Aspect 17: Method according to aspect 16,
wherein a further metal layer is formed on the metal layer and on the shaped body, wherein
the shaped body is arranged in vertical direction between the metal layer and the further metal layer, and
the further metal layer is applied in a structured manner or is structured subsequently, so that the further metal layer has additional separation trenches which extend through the further metal layer along the vertical direction and divide the further metal layer into a plurality of spatially separated sublayers.

Further embodiments and further implementations of the carrier, the component, or the method for producing the carrier or the component will become apparent in the embodiments explained below in connection with FIGS. 1A to 7C.

### BRIEF DESCRIPTION OF THE DRAWINGS

FIGS. 1A, 1B, 1C and 2 show schematic illustrations of some exemplary embodiments of a carrier in sectional views;

FIGS. 3, 4, 5A, 5B and 5C show schematic illustrations of some exemplary embodiments of a component in top views and in sectional views;

FIGS. 6A, 6B, 6C, 6D and 6E show schematic illustrations of some method steps according to an exemplary embodiment of a method for producing a carrier; and

FIGS. 7A, 7B and 7C show schematic illustrations of some further method steps according to a further exemplary embodiment of a method for producing a carrier.

### DETAILED DESCRIPTION OF ILLUSTRATIVE EMBODIMENTS

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

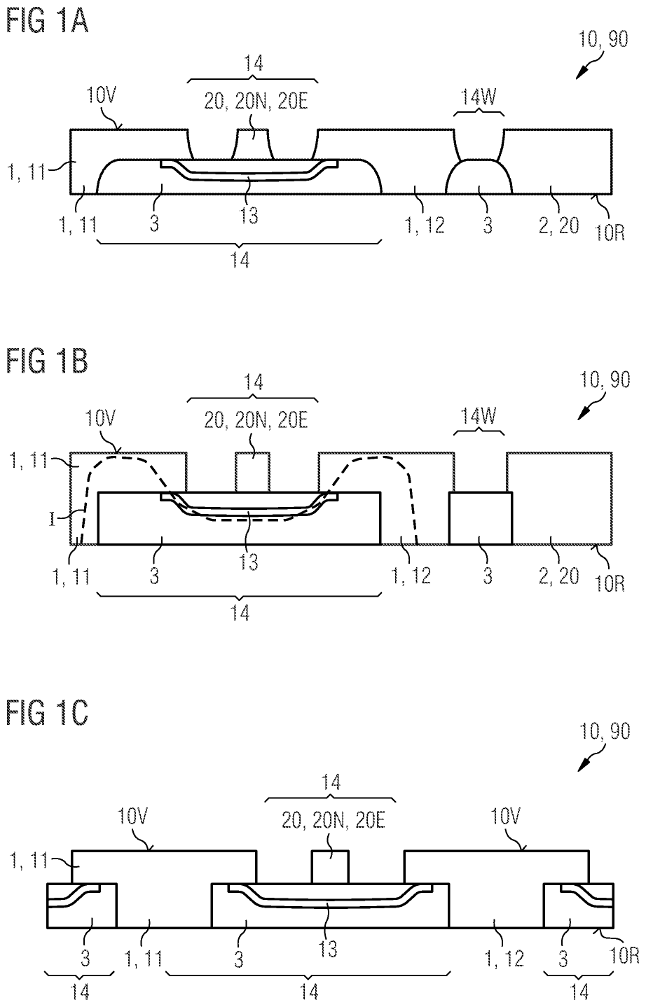

In FIG. 1A, a carrier 90 having a lead frame 10 is schematically shown in sectional view. The carrier has a lead frame 10, a shaped body 3 and at least one electrical connection 13.

The lead frame 10 has at least a first subregion 11, a second subregion 12 and a subsection 20. The subregions 11 and 12 are assigned, for example, to a first electrode 1 of the lead frame 10. Along the lateral direction, the first subregion 11 is spatially spaced from the second subregion 12 by an intermediate region 14. The subsection 20 is located along the lateral direction at least in places between the first subregion 11 and the second subregion 12. The first subregion 11 is electrically conductively connected to the second subregion 12 by the electrical connection 13. Here, the electrical connection 13 can laterally bridge the intermediate region 14.

The intermediate region 14 is partially filled by the shaped body 3. The electrical connection 13 is embedded in the shaped body 3. In top view, the subsection 20 arranged between the subregions 11 and 12 overlaps with the electrical connection 13. The subsection 20 is arranged on the shaped body 3 and is electrically insulated from the electrical connection 13 by the shaped body 3. Since the subsection 20 is arranged only on the shaped body 3 and does not extend through the shaped body 3, its side surfaces are not covered by the material of the shaped body 3. The subsection 20 has a surface facing away from the shaped body 3, which is also not covered by the material of the shaped body 3.

The subsection 20 may be implemented as an electrically neutral subsection 20N or as an electrically non-neutral subsection 20E of the lead frame 10. The electrically non-neutral subsection 20E may be assigned to a second electrode 2 of the lead frame 10. The lead frame 10 has a further subsection 20 assigned to the second electrode 2. Along the lateral direction, the further subsection 20 is spatially spaced from the second subregion 12 of the lead frame 10 by a further intermediate region 14W. The further intermediate region 14W is partially filled by the shaped body 3.

The shaped body 3 can be contiguous, in particular in a one-piece manner. The shaped body 3 mechanically connects the subregions 11 and 12 and the subsections 20. In particular, the shaped body 3 directly adjoins the subregions 11 and 12 and the subsections 20 in places.

The carrier 90 has a top side 10V and a bottom side 10R facing away from the top side 10V. In particular, the bottom side 10R or the top side 10V is formed in places by surfaces of the lead frame 10 and in places by surfaces of the shaped body 3. As schematically shown in FIG. 1A, the intermediate region 14 and the further intermediate region 14W have subregions which are not filled by the material of the shaped body 3. Deviating from FIG. 1A, it is possible for the subregions to be filled with a material of an insulation layer. In this case, the top side 10V may be formed in places by surfaces of the lead frame 10 and in places by surfaces of the insulation layer.

In a departure from FIG. 1A, it is possible for the carrier 90 to have a plurality of first subregions 11, a plurality of second subregions 12, a plurality of electrical connections 13, a plurality of electrically neutral subsections 20N, a plurality of electrically non-neutral subsections 20E, and/or a plurality of further subsections 20. In this case, only a portion of the carrier 90 is schematically shown in FIG. 1A. The carrier 90 may have a plurality of such cutouts that are, for example, immediately adjacent to each other.

A carrier 90 shown in FIG. 1A may be referred to as a 1.5-layer RT-QFN substrate or a 1.5-layer RT-QFN carrier. Such a carrier offers the possibility of rewiring in two independent planes, namely within the shaped body 3 and on the shaped body 3.

A rewiring level takes place within the shaped body 3 by embedding the electrical connection/s 13. The electrical connection 13 may be a metal wire such as a bond-wire. In the case of an Rt-QFN carrier modified by embedded electrical connections, the rewiring takes place in the carrier 90, namely in the shaped body 3. In the 1.5-layer Rt-QFN carrier, the embedded electrical connections 13 represent an electrically independent layer, so that safe rewiring is simplified.

Embedding the electrical connection/s 13 allows greater design freedom than, for example, a 2-layer printed circuit board (PCB: Printed Circuit Board) or a ceramic carrier. In particular, the complex rewiring is not located on the surface of the carrier. Furthermore, no lateral overlap of corresponding connection pads or electrical leads is required. Moreover, the rewiring may be partially implemented below the subsection 20 of the lead frame 10, wherein the subsection 20 may be implemented as a chip pad for receiving a semiconductor chip, a solder pad for receiving a bonding wire connection, a planar electrical connection, or a lead track. The implementation of the rewiring in the shaped body 3 is thus possible in a more space-saving manner than with a conventional PCB.

Compared with PCB substrates, the casting process or the plastic molding process for forming the shaped body 3 or a casting body 4 is less expensive and also easier to perform for a lead frame-based carrier. For example, no bottom side adhesive tape is required in the casting method or the plastic molding method. Compared to PCB substrates, lead frame-based carriers have better thermal properties. Also, PCB substrates are quite limited in design compared to lead frame-based carrier. For example, conventional QFN substrates do not allow free floating conductor tracks or connection pads, or complex structures, and rewiring. Embedded electrical connection 13 eliminates these disadvantages in a carrier 90 described herein.

FIG. 1B shows a simplified illustration of the carrier 90 with the current path I described in FIG. 1A. FIG. 1B shows schematically that the first subregion 11 is electrically conductively connected to the second subregion 12 via the electrical connection 13 embedded in the shaped body 3.

FIG. 1C shows that not only two subregions 11 and 12 can be electrically conductively connected to each other via an electrical connection 13, but several subregions 11 and 12 can be electrically conductively connected to each other via several electrical connections 13 embedded in the shaped body 3. The subsections 20, which are arranged at least in places between the subregions 11 and 12, are arranged on the shaped body 3 and have overlaps with the respective electrical connections 13. Such subsections 20 may be referred to as free-floating conductor tracks or as free-floating connection pads, for example for receiving semiconductor chips or further electrical connections. It is also possible for such subsections 20 to be electrically neutral.

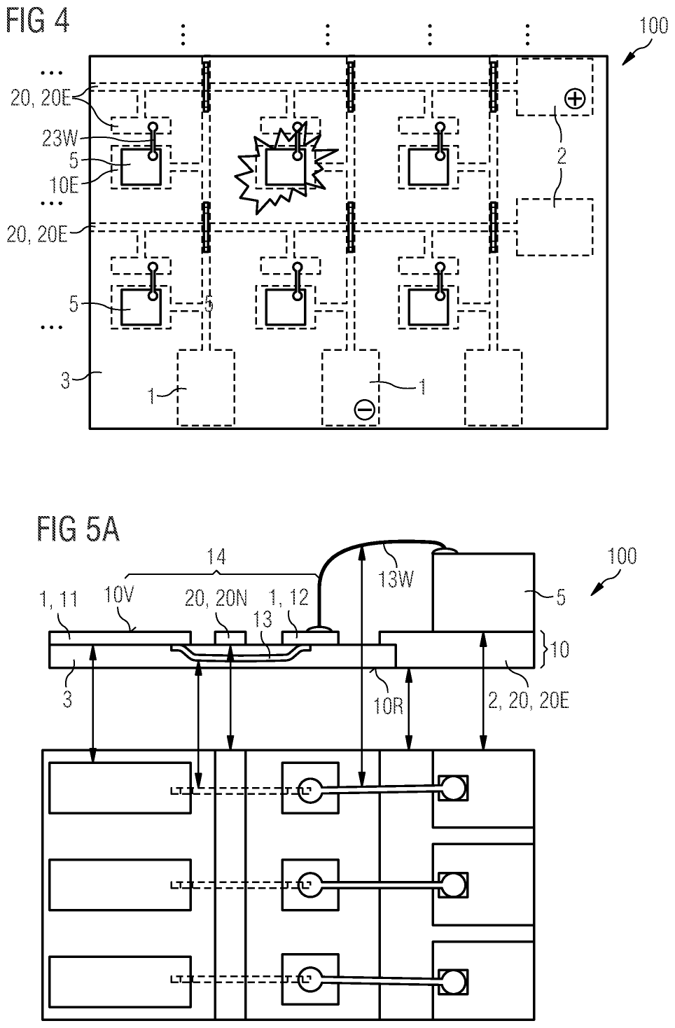

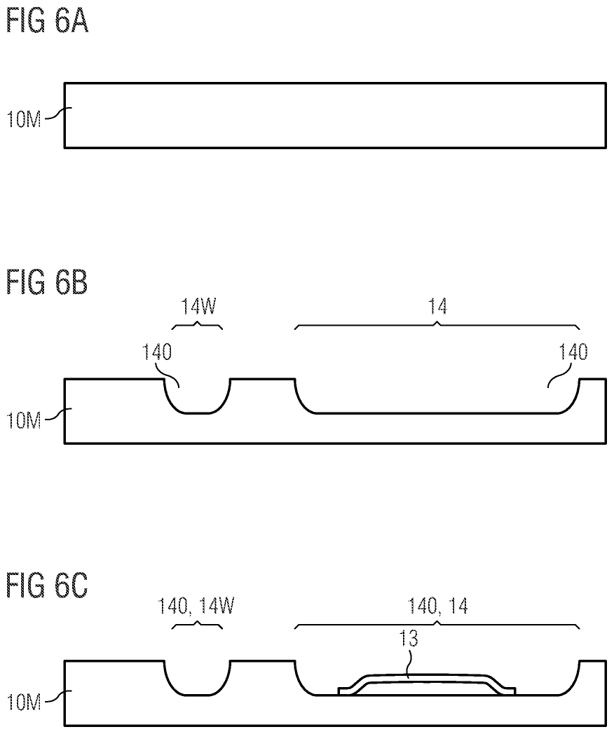

In addition to the free-floating subsection 20 or adjacent free-floating subsections 20, the lead frame 10 has a further subsection 20 extending through the shaped body 3 along the vertical direction. Such a further subsection 20 is schematically shown in FIGS. 1A and 1B. In FIGS. 1A to 1C, subregions 11 and 12 extend along the vertical direction through the shaped body 3. Deviating from this, it is possible for the subregions 11 and 12 to be merely arranged on the shaped body 3 and do not extend throughout the shaped body 3. This is shown schematically in FIG. 3 or 5A, for example.

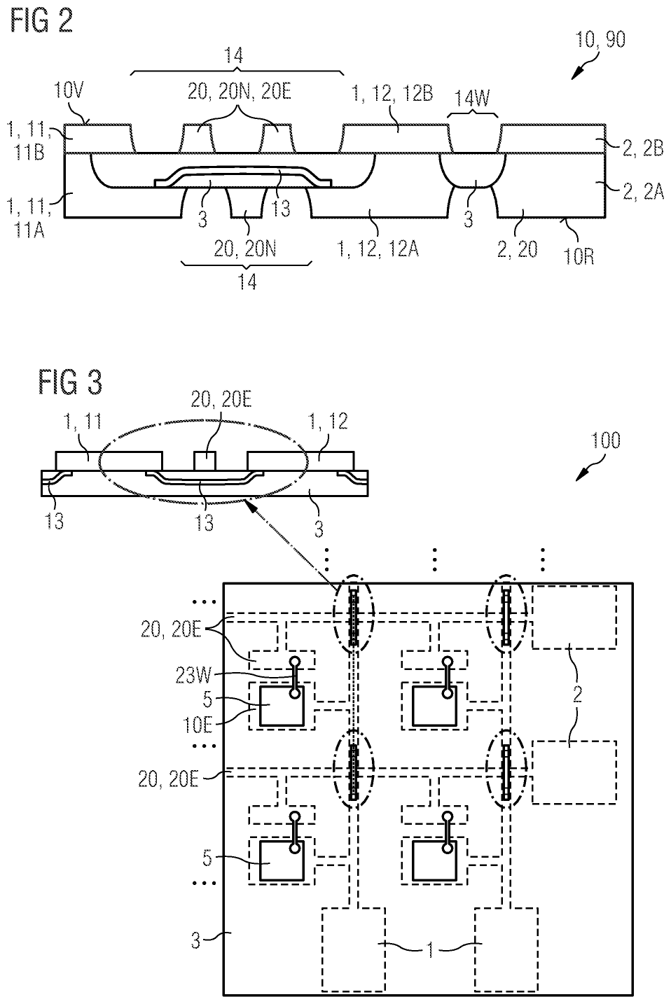

The exemplary embodiment of a carrier 90 shown in FIG. 2 is substantially the same as the exemplary embodiment of a carrier 90 shown in FIG. 1A, except that the carrier 90 has an additional rewiring plane formed on the top side 10V. Compared with FIG. 1A, the carrier 90 is rotated by 180°, with the additional rewiring plane formed on the bottom side 10R of the carrier 90 shown in FIG. 1A.

According to FIG. 2, the first subregion 11 has a first sublayer 11A and a second sublayer 11B disposed on the first sublayer 11A. The second subregion 12 also has a first sublayer 12A and a second sublayer 12B disposed on the first sublayer 12A. The shaped body 3 is arranged along the vertical direction between the first sublayer 11A of the first subregion 11 and the second sublayer 11B of the first subregion 11, or between the first sublayer 12A of the second subregion 12 and the second sublayer 12B of the second subregion 12. The subsection 20 assigned to the second electrode 2 has a first sublayer 2A and a second sublayer 2B.

Furthermore, the lead frame 10 has at least two subsections 20 arranged on different surfaces of the shaped body 3 so that the shaped body 3 with the electrical connection 13 embedded therein is arranged along the vertical direction between the at least two subsections 20. As schematically shown in FIG. 2, a plurality of subsections 20 may be arranged between the first subregion 11 and the second subregion 12 of the lead frame 10. The subsections 20 arranged in the intermediate region 14 do not extend through the shaped body 3 along the vertical direction. These subsections 20 may therefore be referred to as free-floating subsections 20 of the lead frame 10. The subregions 11 and 12 comprising sublayers 11A and 11B and 12A and 12B, respectively, extend throughout the shaped body 3 along the vertical direction and are not referred to as free-floating subregions 11 and 12 of the lead frame 10 in this sense.

Deviating from FIG. 2, it is possible for the shaped body 3 to laterally enclose both the subregions 11 and 12 and the subsection 20 assigned to the second electrode 2. Also in FIG. 2, only a section of the carrier 90 is schematically shown. The carrier 90 may have a plurality of such adjacent cutouts.

The carrier 90 shown in FIG. 2 may be referred to as a 2-layer Rt-QFN substrate or a 2-layer Rt-QFN carrier. Such a carrier offers the possibility of rewiring in three independent planes, namely on the top side 10V, on the bottom side 10R of the lead frame 10 as well as in the shaped body 3. In particular, partial surfaces of the lead frame 10 on the top side 10V and/or on the bottom side 10R can be designed completely freely. The partial surfaces formed by surfaces of the subregions 11 and 12 or by surfaces of the subsections 20 can be formed as mounting surfaces, connection surfaces, solder pads, chip pads, etc.

In the case of a 1.5-layer Rt-QFN carrier (cf. FIGS. 1A-1C), the embedded electrical connections 13 form an electrically independent plane which is not exposed on the top side 10V and/or on the bottom side 10R. It is therefore not necessary to cover the rewiring with solder resist. The bottom side 10R of the carrier 10 can be completely flat.

In a 2-layer Rt-QFN carrier (cf. FIG. 2), the embedded electrical connections 13 represent a third electrically independent layer. This form of rewiring allows greater design freedom than with a 2-layer PCB or with a ceramic substrate. In the case of a 2-layer RT-QFN carrier, the embedded electrical connection 13 can cross several conductive paths on the top side 10V and/or on the bottom side 10R at the same time (cf. FIG. 3).

Rewiring using the embedded electrical connections 13 is possible without affecting the design on the top side 10V and/or on the bottom side 10R. For example, the bottom side 10R has exposed surfaces of the lead frame 10, which are formed as solder pads, for example. These exposed surfaces of the lead frame 10 may be formed by exposed surfaces of the subregions 11 and 12 or the subsections 20. The exposed surfaces of the subregions 11 and 12 or of the subsections 20 on the top side 10V may be formed as mounting surfaces or as connection surfaces which are arranged, for example, to receive semiconductor chips 5 or further electrical connections 13W or 23W, for example, in the form of bonding wires (cf. FIGS. 3, 4 and 5A and 5B). The further electrical connections 13W and/or 23W may also be planar electrical connections. For example, a dielectric may first be applied and an electrical contact deposited thereon. If necessary, another film may be deposited on the further electrical connection 13W or 23W. It is possible for the subsections 20, 20N or 20E located on the top side 10V to have overlaps or not to have overlaps with the surfaces of the subregions 11 and 12 or the subsections 20 on the bottom side 10R of the carrier 90.

Depending on the layout, the rewiring level within the shaped body 3 is in particular not exposed. Therefore, it is not necessary to cover this rewiring plane, for example with a solder resist. With a suitable layout of the carrier 90, it is possible in many cases to use an existing ASIC chip for a new design, wherein the arrangement of the I/Os does not directly match the desired layout of the solder pads, without using long or crossing bonding wires. This significantly saves development time and cost. Furthermore, the rewiring can even be partially done under a bonding wire pad or under a chip pad, for example for an ASIC or a photodiode chip. This leads to the drastic saving of space, so that a component 100 with such a carrier 90 can be made as compact and small as possible.

FIG. 3 shows a possible application of a carrier 90 described here. The component 100 has a carrier 90 and a plurality of semiconductor chips 5 arranged on the carrier 90. The first subregions 11 and the second subregions 12 are formed, in particular, as conductor tracks and are assigned to a first electrode 1. A plurality of subsections 20 or 20E may be implemented as conductive tracks assigned to a second electrode 2. Due to the rewiring within the shaped body 3, the conductor tracks may be located on the same rewiring plane and cross each other. At the crossing points, there is an interruption of one conductor path, as a result of which the other conductor path arranged on the shaped body 3 overlaps or crosses with the electrical connection 13 embedded in the shaped body 3.

The lead frame 10 has further subregions 10E and further subsections 20E. In particular, the further subregions 10E are assigned to the first electrode 1. The further subsections 20E may be assigned to the second electrode 2. The semiconductor chips 5, which may be ASIC chips or light-emitting diodes or other electrical or optoelectronic components, are arranged in particular on the further subregions 10E and are electrically conductively connected thereto. The further subsections 20E are in particular configured to receive further electrical connections 23W. The further electrical connections 23W may be bonding wires or planar electrical connections which electrically conductively connect the subsections 20E to the semiconductor chips 5.

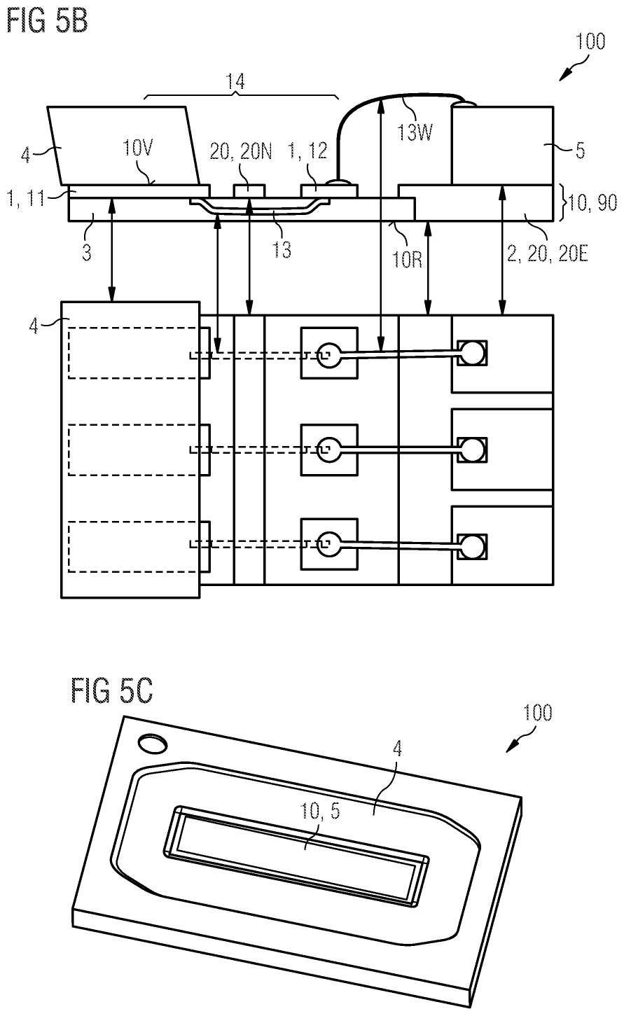

FIG. 3 shows a component 100 with a plurality of semiconductor chips 5 which can be in each case, i.e. individually, electrically activated or controlled. This is shown schematically in FIG. 4, for example. According to FIGS. 3 and 4, the component 100 may have a plurality of electrode surfaces. By selective electrical contacting at the electrode surfaces, the semiconductor chips 5 can be electrically activated individually or in groups. In this sense, the semiconductor chips 5 can be electrically controlled individually.

According to FIGS. 3 and 4, the semiconductor chips 5 are arranged in a matrix-like manner on the carrier 90. In particular, the semiconductor chips 5 are LEDs. The individual semiconductor chips 5 may be interleaved with the sample contacts at the edge of the component 100 to test the functionality of the individual semiconductor chips 5. The component 100 shown in FIGS. 3 and 4 can be singulated into smaller components 100. The electrical conductors, i.e., the subregions 11 and 12 formed as conductors, may be located in saw trenches and may be completely removed after singulation.

FIG. 5A shows another exemplary embodiment of a carrier 90 or a component 100 with such a carrier 90. The carrier 90 has a subsection 20 which is formed as an electrically neutral subsection 20N. In top view, the subsection 20 may overlap with a plurality of electrical connections 13 embedded in the shaped body 3. The subsection 20N of the lead frame 10 may be configured as a sealing lip, which is arranged in the lateral direction between the first subregion 11 and the second subregion 12 of the first electrode 1. In particular, the subsection 20N formed as a sealing lip is configured to prevent the second subregion 12 from being covered by a casting material of a casting body 4. Such a casting body 4 is schematically shown, for example, in FIGS. 5B and 5C.

In particular, the casting body 4 frames an inner region of the component 100. In top view, the casting body 4 may partially or completely cover the first subregion 11 or a plurality of first subregions 11. Due to the presence of the subsection 20 configured as a sealing lip, material of the casting body 4 may be prevented from reaching the inner region of the component 100 and thus the semiconductor chips 5 when the casting body 4 is attached. The component 100 may have a plurality of casting bodies 4, each laterally surrounding one of the semiconductor chips 5. Such a component 100 may be singulated into smaller components 100 each having one of the casting bodies 4.

Such a component 100 has a so-called deflashing-free design. Material of the casting body 4 can be effectively kept away from the inner portion of the component 100 and thus from the semiconductor chips 5. For example, it is possible for the casting body 4 to be adjacent to the subsection 20N formed as a sealing lip. The subregions 12 as well as further subsections 20, on which the semiconductor chips 5 are arranged, remain free from being covered by material of the casting body 4 even without a so-called deflashing step.

The embedded electrical connections 13 thus enable the formation of effective flash and bleed-stop structures, which seal further electrical connections 13W, in particular in the form of bonding wires (see FIG. 5B) or in the form of planar electrical connections 13W, and as well as surfaces of the subregions 12 for receiving the further electrical connections 13W against casting material in a space-saving manner. A deflashing step can be omitted, as a result of which the component 100 is possibly not mechanically pre-damaged.

Lower thickness tolerances can also be achieved with a carrier 90 described herein. In particular, the thickness tolerances of lead frame-based Rt-QFN carriers are considerably smaller than those of, for example, a PCB or ceramic substrate. A casting process with exposed semiconductor chips 5 is greatly facilitated in a carrier 90 with an internal rewiring.

In a conventional QFN process, the lead frame 10 is often perforated many times during transfer molding and is surrounded by the casting material. The solder pads should also be pressed firmly onto the shaped body 5 by pressure from above to prevent what is known as inflating. In many cases, this is not sufficiently possible. In addition, the solder pads or the soldering surfaces on the bottom side should be covered with adhesive tape on the bottom side during the casting process. So-called “floating” connection pads, bonding wire pads or chip pads are generally not possible with adhesive tape on the bottom side.

However, there are no openings in a carrier 90 described here. In addition, the top side 10V and the bottom side 10R are mechanically sealed from each other. The bottom side 10R, which may be a solder side, is not contaminated with casting material.

In Rt-QFN devices, minimum structure sizes are often defined by half etches and are therefore significantly smaller. This allows space-saving flash stop structures to be introduced around connection pads, chip pads and bonding wire pads, for example in the form of sealing lips described above. In contrast, flash-stop structures in conventional QFN carriers are often in the form of wide trenches. This is very space-consuming, as the width of such a trench is often greater than 100 μm and/or is based on the total material thickness. In addition, a minimum distance to a wall of a cavity wherein the semiconductor chip is arranged, including tolerances, is required. A flash stop design is therefore often out of the question when space is limited by conventional carriers.

In a carrier 90 described herein, flash stop structure can be generated by a raised structure, such as subsection 20N, shown schematically in FIGS. 5A and 5B. The subsection 20N may be frame-like and may serve as a perimeter barrier to protect the terminal pads or bonding wire pads from casting material. The connection pads or bonding wire pads may be formed by surfaces of the second subregions 12. The electrical connections between the first subregions 11 and the second subregions 12 are achieved by the electrical connections 13 embedded in the shaped body 3, which dip under the flash stop structure. This is not possible in this form for a conventional 2-layer PCB or ceramic substrate. For a comparable flash-stop structure, another layer is often required, for example in the form of a solder-stop lacquer belt.

In a carrier 90 described herein, the bottom side 10R of the carrier 90 is deflashed. Therefore, a deflashing-free design of the top side 10V allows for an overall elimination of a deflashing step. There are also no gaps or channels from the top side 10V to the bottom side 10R through which casting material, interconnect material, or encapsulation material such as silicone can reach the solder pads on the bottom side 10R. Therefore, adhesive tape on the bottom side to protect the solder pads on the bottom side 10R from contamination is not required.

The thickness tolerances of a carrier 90 described here are significantly smaller than those of a comparable PCB or ceramic substrate. In the case of a 1.5-layer Rt-QFN carrier, these are approximately +/−15 μm, which is significantly smaller than for a comparable conventional 2-layer PCB substrate, whose thickness tolerances are often +/−70 μm.

Furthermore, with a carrier 90 described herein, a film-assisted molding process can be easily performed due to the small height differences on the top side 10V. This is often not possible with conventional substrates with rewiring without embedded electrical connections, for example, a PCB or ceramic substrate.

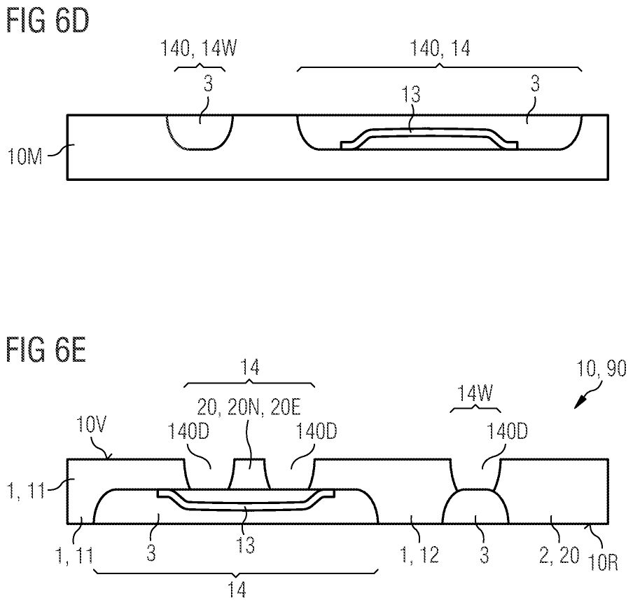

FIGS. 6A, 6B, 6C, 6D, and 6E show schematic illustrations of some method steps according to an exemplary embodiment of a method for producing a carrier 90 described herein.

According to FIG. 6A, a contiguous metal layer 10M is provided. The metal layer 10M can be made of copper or of a material similar in electrical and/or thermal conductivity.

Referring to FIG. 6B, separation trenches 140 are formed in the metal layer 10M. For example, the metal layer 10M is etched, such as semi-etched. Even in the presence of the separation trenches 140, the metal layer 10M initially remains contiguous. At least one electrical connection 13 is provided in at least one of the separation trenches 140. Referring to FIG. 6C, the electrical connection 13 is initially in direct electrical contact with the entire metal layer 10M. Multiple electrical connections 13 may be formed in multiple separation trenches 140.

According to FIG. 6D, the separation trenches 140 are filled with material of the shaped body 3, as a result of which the electrical connection 13 is embedded in the shaped body 3. The separation trenches 140, in which no electrical connections 13 are arranged, can also be filled with the material of the shaped body 3.

According to FIG. 6E, further separation trenches 140D are formed through the metal layer 10M for partial exposure of the shaped body 3. In top view, the further separation trenches 140D each overlap with one of the separation trenches 140. It is possible that several separation trenches 140D overlap with the same separation trench 140. By means of the separation trenches 140 and the further separation trenches 140D, the contiguous metal layer 10M is divided into at least a first electrode 1 and a second electrode 2 different from the first electrode 1, in particular into a plurality of subregions 11 and 12 as well as into a plurality of subsections 20. This is shown schematically in FIG. 6E. The exemplary embodiment of a carrier 90 shown in FIG. 6E corresponds to the exemplary embodiment of a carrier 90 shown in FIG. 1A.

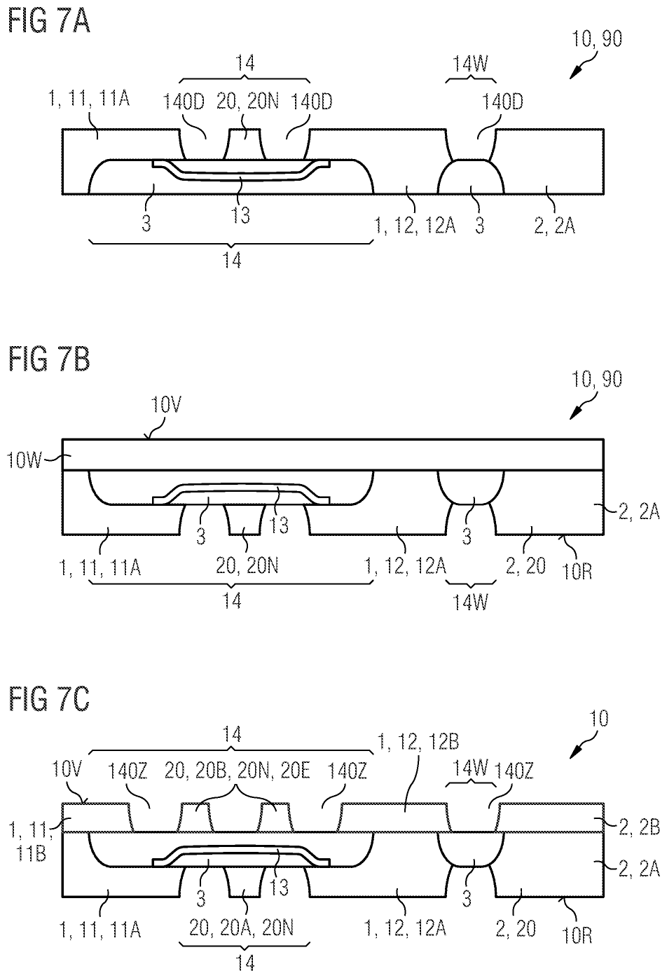

FIGS. 7A, 7B and 7C show schematic illustrations of further method steps of a method for producing a carrier 90, in particular the carrier 90 shown in FIG. 2.

First, the carrier 90 shown in FIG. 6E is provided (FIG. 7A). According to FIG. 7B, a further metal layer 10W is formed on the structured metal layer 10M and on the shaped body 3. The shaped body 3 is located along the vertical direction between the metal layer 10M and the further metal layer 10.

The further metal layer 10W can initially be applied over the entire surface. In a further process step, additional separation trenches 140Z are formed by the further metal layer 10W. In top view, the additional separation trenches 140Z may each overlap with one of the separation trenches 140 and/or 140D. Alternatively, it is possible that the further metal layer 10W is applied in a structured manner, for example by using a mask, so that the further metal layer 10W has additional separation trenches 140Z extending through the further metal layer 10W along the vertical direction. The additional separation trenches 140Z divide the further metal layer 10W into a plurality of spatially separated sublayers 11B, 12B, 2B, 20B. The exemplary embodiment of a carrier 90 shown in FIG. 7C corresponds to the exemplary embodiment of a carrier 90 shown in FIG. 2.

Since a first sublayer 11A of the first subregion 11, a first sublayer 12A of the second subregion 12, a first sublayer 2A of the second electrode 2, and a first sublayer 20A shown as a subsection 20 in FIG. 7C are formed from the metal layer 10M, these sublayers 11A, 12A, 2A, and 20A may be formed from the same material.

Since a second sublayer 11B of the first subregion 11, a second sublayer 12B of the second subregion 12, a second sublayer 2B of the second electrode 2, and a second sublayer 20B shown in FIG. 7C and formed as a further subsection 20 originate from the further metal layer 10W, these sublayers 11B, 12B, 2B and 20B may be formed from the same material. The metal layer 10M and the further metal layer 10W may be formed of the same material or of different materials.

The invention is not restricted to the exemplary embodiments by the description of the invention made with reference to exemplary embodiments. The invention rather comprises any novel feature and any combination of features, including in particular any combination of features in the claims, even if this feature or this combination is not itself explicitly indicated in the claims or exemplary embodiments.

1.-18. (canceled)

19. A carrier comprising:
a shaped body;
a lead frame; and
a first electrode and a second electrode different from the first electrode,
wherein the first electrode comprises a first subregion of the lead frame, a second subregion of the lead frame, and an electrical connection, the electrical connection electrically connecting the first subregion to the second subregion,
wherein the first subregion is laterally spaced from the second subregion by an intermediate region,
wherein the lead frame has at least one subsection, which is located at least in places in the intermediate region and thus in lateral directions between the first subregion and the second subregion of the first electrode,
wherein the intermediate region is at least partially filled by the shaped body or directly adjoins the shaped body, the electrical connection being embedded in the shaped body, and
wherein the subsection of the lead frame is neither a subregion of the first electrode nor a subregion of the second electrode.

20. The carrier according to claim 19, wherein the subsection is electrically insulated from the electrical connection by the shaped body and overlaps with the electrical connection in a top view on the shaped body.

21. The carrier according to claim 19, wherein the subsection is free from lateral covering by material of the shaped body.

22. The carrier according to claim 19,
wherein the carrier has a top side configured to receive at least one semiconductor chip,
wherein the top side is formed in places by surfaces of the first subregion, of the second subregion and/or of the subsection, and
wherein the top side is free from being covered by material of the shaped body.

23. The carrier according to claim 19, wherein the first subregion and the second subregion are enclosed in lateral directions by the shaped body so that the first subregion and the second subregion are mechanically connected to one another by the shaped body.

24. The carrier according to claim 19, wherein the first subregion, the second subregion and the subsection of the lead frame comprise the same material.

25. The carrier according to claim 19, wherein the subsection of the lead frame is configured to be electrically neutral.

26. The carrier according to claim 25, wherein the subsection of the lead frame is formed as a sealing lip, which is arranged in a lateral direction between the first subregion and the second subregion of the first electrode, and wherein the sealing lip is configured to prevent the second subregion from being covered by a casting material.

27. The carrier according to claim 19, further comprising:
a further subsection of the lead frame,
wherein the first subregion, the second subregion and the further subsection of the lead frame are each made in one-piece, and
wherein the further subsection is a subregion of the second electrode.

28. The carrier according to claim 19,
wherein each of the first subregion and the second subregion comprises at least two sublayers arranged one above the other,
wherein the lead frame has at least one further subsection in addition to the subsection, and
wherein the shaped body with the electrical connection embedded therein is arranged along a vertical direction between the subsection the further subsection.

29. The carrier according to claim 28, wherein, the further subsection is assigned to the second electrode.

30. The carrier according to claim 27,
wherein the first subregion comprises a first sublayer and a second sublayer disposed on the first sublayer,
wherein the second subregion comprises a first sublayer and a second sublayer disposed on the first sublayer,
wherein the shaped body is arranged along a vertical direction between the first sublayer of the first subregion and the second sublayer of the first subregion,
wherein the first sublayer of the first subregion and the first sublayer of the second subregion comprise the same material, and
wherein the second sublayer of the first subregion and the second sublayer of the second subregion comprise the same material.

31. The carrier according to claim 27, wherein the first subregion, the second subregion or/and the further subsection is/are formed as electrical conductor track/s on the shaped body.

32. The carrier according to claim 27, wherein the first subregion, the second subregion or the further subsection comprises a mounting surface configured to receive a semiconductor chip or a further electrical connection of the first electrode or a further electrical connection of the second electrode.

33. A component comprising:
the carrier according to claim 19; and
at least one semiconductor chip,
wherein the semiconductor chip is arranged on the carrier and electrically conductively connected to the lead frame, and
wherein the semiconductor chip is spatially spaced from the shaped body and thus is not covered by the shaped body.

34. A method for producing a carrier comprising a lead frame and a shaped body, the method comprising:
providing a contiguous metal layer;
forming separation trenches in the metal layer such that the metal layer initially remains contiguous;
providing at least one electrical connection in at least one of the separation trenches;
filling the separation trenches with material of the shaped body thereby embedding the electrical connection in the shaped body; and
forming further separation trenches through the metal layer to partially expose the shaped body, the further separation trenches each overlapping with one of the separation trenches such that the contiguous metal layer is divided by the separation trenches and the further separation trenches into at least a first electrode and a second electrode different from the first electrode,
wherein the first electrode comprises at least a first subregion and a second subregion of the lead frame and the electrical connection,
wherein the electrical connection electrically conductively connects the first subregion to the second subregion,
wherein the first subregion is laterally spaced from the second subregion by an intermediate region,
wherein the lead frame has at least one subsection which is located in the intermediate region and thus in lateral directions between the first subregion and the second subregion of the first electrode, and
wherein the intermediate region is at least partially filled by the shaped body or directly adjoins the shaped body.

35. The method according to claim 34,
wherein a further metal layer is formed on the metal layer and on the shaped body,
wherein the shaped body is arranged in a vertical direction between the metal layer and the further metal layer, and
wherein the further metal layer is applied in a structured manner or is structured subsequently so that the further metal layer has additional separation trenches which extend along the vertical direction through the further metal layer and divide the further metal layer into a plurality of spatially separated sublayers.

36. The method according to claim 34, wherein the electrical connection is placed in at least one of the separation trenches, the electrical connection being initially in direct electrical contact with the entire metal layer.
